(19) United States
(12) Patent Application Publication
(10) Pub. No.: US 2016/0372034 A1
(43) Pub. Date: Dec. 22, 2016

(54) Shift Register and OLED Display Drive Circuit

(71) Applicant: EverDisplay Optronics (Shanghai) Limited, Shanghai (CN)

(72) Inventor: Sisi Zhou, Shanghai (CN)

(21) Appl. No.: 15/187,031

(22) Filed: Jun. 20, 2016

(30) Foreign Application Priority Data
Jun. 19, 2015 (CN) 201510348937.2

(51) Int. Cl. G09G 3/3225; G11C 19/28

(52) U.S. Cl. CPC G09G 3/3225; G11C 19/28; G09G 2300/0852; G09G 2300/0871; G09G 2310/061; G09G 2310/08

(57) ABSTRACT

The present invention relates to the field of display, and more particularly, to a display device used for Gate on Array and the related, and to a multi-stage shift register comprised by basic drive circuit, in the multistage drive modules, the output signal of the driver module at any stage acts as the reset signal of the adjacent previous-stage driver module and acts as the input signal of the adjacent next-stage driver module, the collection of the output signals correspondingly generated by driver modules in multi-stages constitutes a series of non-overlapping temporal pulse signals.

### The present application claims priority to and the benefit of Chinese Patent Application No. 201510348937.2, filed on Jun. 19, 2015, the entire content of which is incorporated herein by reference.

### FIELD OF THE INVENTION

The invention relates to the field of display, and more particularly, to a display device used for Gate on Array and the related, and to a multi-stage shift register comprised by basic drive circuits.

### DESCRIPTION OF THE RELATED ART

In the more traditional prior art, with the wide use of the passive matrix organic light emitting diode (PMOLED) in display in the industry, if one tries to increase the panel size of the display to meet consumer demand, it is needed to make the drive time of individual pixel become shorter, which accordingly requests increasing the transient current, while power dissipation and pressure drop of ITO traces will become larger, which reduces the efficiency of display. As another preferred options, the industry also designed active matrix organic light emitting diode (AMOLED) which progressive scans inputting OLED current through the switch, which can solve these problems. And because of the advantages of high brightness, wide viewing angle and fast response speed of the applied AMOLED, it was more and more widely used in high performance display devices. Gate on Array (GOA) integrates grid switching circuits in an array substrate in order to achieve high integration of the drive circuit.

FIG. 1 is a design scheme of a typical GOA circuit in prior art, mainly comprising seven thin film TFT transistors that are illustrated as PMOS transistors M10˜M16, and further comprising two capacitors C10˜C20, the main problem is the excessive number of transistors used in the GOA circuit resulting in increase of the layout space, which is obviously unable to meet the needs of narrow frame design of displays, besides, excessive number of transistors also significantly reduces yields, the invention will introduce the design using fewer total transistors in drive circuit in the following, to avoid these problems.

### SUMMARY OF THE INVENTION

To solve the above technical problems, the application provides a shift register, including drive modules in multi-stages, wherein:

output signals of a current-stage driver module act as reset signals of a previous-stage driver module and act as input signals of a next-stage driver module;

each of the drive modules has a first clock control terminal and a second clock control terminal; in two adjacent drive modules of the drive modules, the first clock control terminal of the previous-stage driver module is driven by a first clock signal, and the second clock control terminal of the previous-stage driver module is driven by a second clock signal inverted with the first clock signal; the first clock control terminal of the next-stage driver module is driven by the second clock signal, and the second clock control terminal of the next-stage driver module is driven by the first clock signal.

As a preferred embodiment, the above mentioned shift register, wherein each of the drive modules includes a first node, a second node, a first transistor, a second transistor, a third transistor and a fourth transistor, and each of the transistors has a first end, a second end and a control terminal;

wherein, the second end of the first transistor and the first end of the second transistor are connected to the control terminal of the third transistor through the first node, the second end of the third transistor and the first end of the fourth transistor are connected to the second node, and a bootstrap capacitor is disposed to be connected between the second node and the first node, so as to generate the output signals of each of the drive modules at the second node.

As a preferred embodiment, the above mentioned shift register, wherein the control terminals of the first transistor and of the fourth transistor are connected to the first clock control terminal of each of the drive modules, the first end of the third transistor connects to the second clock control terminal of each of the drive module.

As a preferred embodiment, wherein the first end of the first transistor of the current-stage drive module is configured to receive the input signals and connected to an output signal end of the previous-stage drive module, and the control terminal of the second transistor of the current-stage drive module is configured to receive the reset signals and connected to the output signal ends of the next-stage drive module.

As a preferred embodiment, the above mentioned shift register, wherein the second ends of the second transistor and of the fourth transistor are connected to a reference voltage source, so as to receive a high-level reference voltage.

As a preferred embodiment, the above mentioned shift register, wherein the drive modules in multi-stages are arranged in a row; the first clock control terminals of the drive modules in odd-numbered rows are driven by the first clock signal, and the second clock control terminals of the drive modules in odd-numbered rows are driven by the second clock signal; the first clock control terminals of the drive modules in even-numbered rows are driven by the second clock signal, and the second clock control terminals of the drive modules in even-numbered rows are driven by the first clock signal.

The present application also provides a drive circuit, comprising a first node, a second node, a first transistor, a second transistor, a third transistor and a fourth transistor, and each of the transistors has a first end, a second end, and a control terminal;

wherein, the second end of the first transistor and the first end of the second transistor are connected to the control terminal of the third transistor through the first node; the second end of the third transistor and the first end of the fourth transistor are connected to the second node, and a bootstrap capacitor is disposed to be connected between the second node and the first node, so as to generate the output signal of the drive module at the second node.

As a preferred embodiment, the above mentioned drive circuit, further comprising:

a first clock control terminal, connecting the control terminal of the first transistor and the control terminal of the fourth transistor;

a second clock control terminal, connecting the first end of the third transistor;

wherein, the first end of the first transistor is configured to receive an input signal, and the control terminal of the second transistor is configured to receive a reset signal.

As a preferred embodiment, the above mentioned drive circuit, wherein the second end of the second transistor and of the fourth transistor are connected to a reference voltage source, so as to receive a high-level reference voltage.

As a preferred embodiment, the above mentioned drive circuit, wherein the first transistor, the second transistor, the third transistor and the fourth transistor are all PMOS transistors.

### BRIEF DESCRIPTIONS OF THE DRAWINGS

The accompanying drawings, together with the specification, illustrate exemplary embodiments of the present disclosure, and, together with the description, serve to explain the principles of the present invention.

FIG. 1 shows a basic structure of GOA circuit in the prior art;

FIG. 2 shows a circuit structure of the drive module of the present invention;

FIG. 3 shows a schematic diagram of driver modules in multi-stages in series with each other;

FIG. 4 shows a schematic diagram of the sequential control program adopted;

FIGS. 5A-5E show the schematic diagrams of the response of each transistor of driver modules during the implementation of sequential control program.

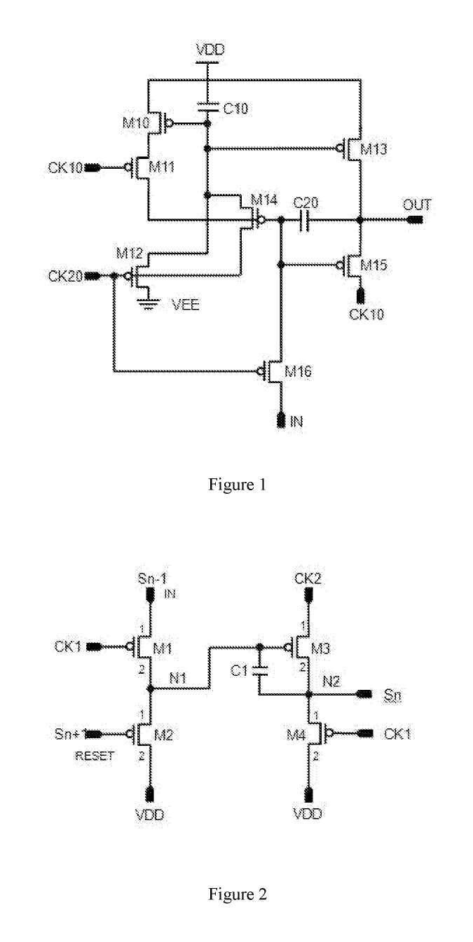

### DETAILED DESCRIPTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “plurality” means a number greater than one.

Hereinafter, certain exemplary embodiments according to the present disclosure will be described with reference to the accompanying drawings.

In the industry, Gate on Array (GOA) integrates grid switching circuits in an array substrate in order to achieve high integration of the drive circuits, which is an excellent choice for both saving material and reducing process steps. Especially, AMOLED is based on the technology of low temperature polysilicon, thin film transistors (TFT) of drive panel has a high mobility, which is more conducive to the integration of GOA circuits.

Refer to FIG. 2, showing a GOA drive circuit. A drive module/circuit mainly includes the first to fourth transistors M1˜M4, we can interconnect the second end of the first transistor M1 and the first end of the second transistor M2 at a first common node N1, and interconnect the second end of the third transistor M3 and the first end of the forth transistor M4 at a second common node N2. In some embodiments, the first transistor M1 to the fourth transistor M4 can be P-type thin film transistor TFT; wherein, the first common node N1 connects to the control terminal of the third transistor M3, and a bootstrap capacitor C1 is disposed to be connected between the second common node N2 and the first common node N1, we set that the drive module finally outputs the output signal Sn of the drive module at the second common node N2. In addition, we set in advance that the control terminals of the first transistor M1 to the fourth transistor M4 are for example grid electrodes, and when the first ends of the transistors are the sources/drains, the second end are the drains/sources, as an electronic switch, a control terminal of the transistor can control the on or off between the first end and the second end.

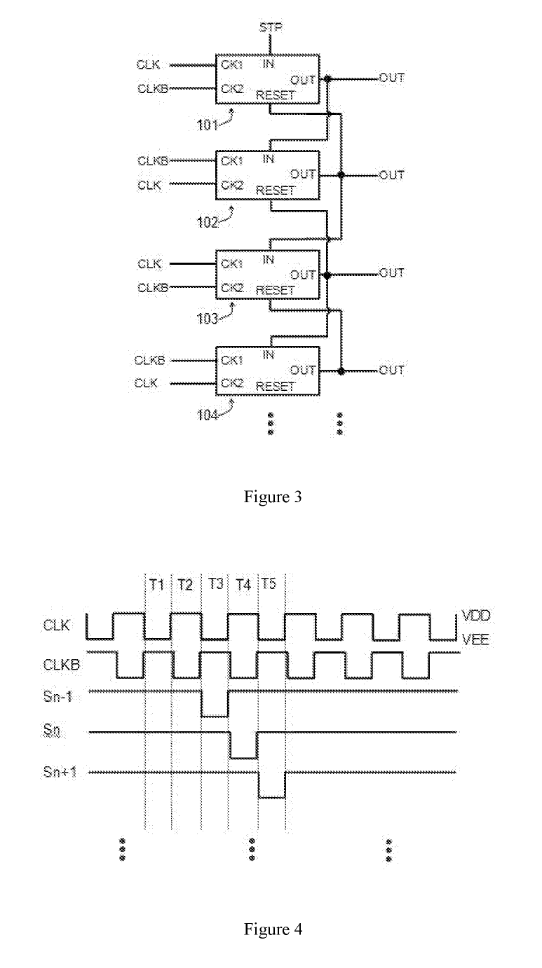

Specifically, in the driving module, the control terminal of the first transistor M1 and the control terminal of the fourth transistor M4 are connected to each other and both connects to the first clock control terminal CK1 of the drive module, and the first end of the third transistor M3 is connected to the second clock control terminal CK2 of the drive module. When the first clock signal CLK is applied to the first clock control terminal CK1, namely, is respectively applied to the grid control ends of the first transistor M1 and the fourth transistor M4, it also requires that an inverted signal or a complementary signal of the first clock signal, that is another second clock signal CLKB is simultaneously applied to the second clock control terminal CK2, i.e., is applied to the first end of the third transistor M3, e.g., the drive module 101 in FIG. 3 is applied to the first clock control terminal CK1 and second clock control terminal CK2. Vice versa, when the second clock signal CLKB is applied to the first clock control terminal CK1, it also requires that the first clock signal CLK is simultaneously applied to the second clock control terminal CK2, e.g., the drive module 102 in FIG. 3 is applied to the first clock control terminal CK1 and second clock control terminal CK2. The first clock control terminal CK1 of the previous-stage driver module 101 is driven by the first clock signal CLK, and the second clock control terminal CK2 is driven by the inverted second clock signal CLKB; the first clock control terminal CK1 of the next-stage driver module 102 is driven by the second clock signal CLKB, and the second clock control terminal CK2 is driven by the first clock signal CLK, the connection of the clock control terminals of adjacent two drive modules are opposite, which will be illustrated in detail in the following.

In FIG. 2, the second end of the second transistor M2 and the second end of the fourth transistor M4 are input by a high level reference voltage VDD. For the drive module in multi-stages, in a selected current-stage driver module, the first end of the first transistor M1 is used for receiving an input signal IN, we define the input signal IN of the current-stage drive module as substantially the output signal Sn−1 of the previous-stage drive module, so the first end of the first transistor M1 of the current-stage drive module should be coupled to the second common node of the previous-stage drive module, for receiving the output signal Sn−1 of the previous-stage drive module. Likewise, also in a selected current-stage driver module, the gate control terminal of the second transistor M2 is used for receiving a reset signal or a reset signal RESET, we define the reset signal RESET of the current-stage drive module as substantially the output signal Sn+1 of the next-stage driver module, so the control terminal of the second transistor M2 of the current-stage drive module should be coupled to the second common node of the next-stage drive module, for receiving the output signal Sn+1 of the next-stage drive module.

In fact, a shift register or a complete Gate on Array (GOA) should include multistage single drive modules shown in FIG. 2. Now take FIG. 3 as an example to clarify, driver modules in multi-stage set in a cascade way are in series, the multistage drive modules at least include the first row driver module 101, the second row drive module 102, the third row drive module 103, the fourth row driver module 104, . . . and the N-th row drive module, etc., these driver modules in multi-stage are connected in series to form a column. We can easily find some rules, for example, an output signal of the current-stage drive module 102 serves as a reset signal RESET of the adjacent previous-stage drive module 101, and also serves as the input signal IN of the adjacent next-stage drive module 103, other drive modules like drives modules 103, 104 also follow this rule. More specifically, the industry generally designates a frame open signal STP-1 applied to the input signal IN of the first row driver module 101, accordingly, the reset signal RESET of the last row drive module at the end position of the driver modules in multi-stage is also designated to apply another similar frame open signal STP-2, but in some conditions which is not very strict, it also allows not applying an input signal to the reset end RESET of the last row drive module, but because the last row drive module has not been reset, it will lead to the situation the output end of the last row drive module may have been in the output state that is Multi-out state.

In order not to causing ambiguity or understanding deviation because of the wording of the terms of this article, we define the positional relationship between the drive modules of this level and upper level, next level, and define the positional relationship of drive modules of adjacent front level and latter level. For example, in FIG. 3, in addition to the first and last rows drive modules which are at the special position, taking a current-stage drive module N (such as 103) as an example, the current-stage driver module N (such as 103) has an adjacent previous-stage drive module N−1 (e.g. 102) and an adjacent next-stage drive module N+1 (e.g. 104), N is a natural number not less than 2. However, for the two adjacent driver modules N, N+1 (e.g. 103, 104), the drive module N (e.g. 103) belongs to the previous-stage driver module and the drive module N+1 (e.g. 104) belongs to the next-stage driver.

In this way, we will elaborate such kind of sample in the following: the output signal SN of any current-stage drive module N serves as the reset signal RESET of adjacent previous-stage drive module N−1 and also servers as the input signal IN of the adjacent next-stage driver module N+1, we also define in the adjacent drive modules N−1 and N, the first clock control terminal CK1 of the previous-stage drive module N−1 is driven by the first clock signal CLK and its second clock terminal CK2 is driven by the second clock signal CLKB, the first clock control terminal CK1 of the next-stage drive module N is driven by the second clock signal CLKB and its second clock terminal CK2 is driven by the first clock signal CLK. In some alternative embodiments, in the driver modules in multi-stage arranged in a column, the first clock control terminals CK1 of the drive modules 101, 103 in odd-numbered rows are driven by the first clock signal CLK, and their second clock control terminal CK2 is driven by the second clock signal CLKB, opposed to this is, the first clock control terminals CK1 of the drive modules 102, 104 in even-numbered rows are driven by the second clock signal CLKB and their second clock control terminal CK2 is driven by the first clock signal CLK.

Referring to FIG. 4, take a predetermined cycle period (such as a conventional half-frame period) as an example to illustrate the working mechanism of driver modules in multi-stage. Within the predetermined time period, the first clock signal CLK and the second clock signal CLKB are inverted signals to each other in each unit of the time period, and the logic state of the first clock signal CLK in the next unit of the time period contraries to the logic state of it in adjacent previous unit of the time period, and so does the second clock signal CLKB, which shows the self-characteristic of the clock signal. Now we take a sequential control program performed in the first to fifth unit period T1˜T5 within the predetermined time period as an example to show the periodic change of the first clock signal CLK and the second clock signal CLKB, the first to fifth unit period T1˜T5 is continuous in the timeline. In the period of the first, third and fifth units T1, T3, T5 of the time period, the first clock signal CLK is at a low logic level and the second clock signal CLKB is at a high logic level, also in the period of the second and fourth units T2, T4 of the time period, the first clock signal CLK is at a high logic level and the second clock signal CLKB is at a low logic level. In some alternative embodiments, the first clock signal CLK or the second clock signal CLKB can reach the level of a high level reference voltage VDD such as 5.5V˜7.5V when it is at the high level, and it can reduce to the level of a low level reference voltage VEE such as negative −7V˜−9V when at the low level.

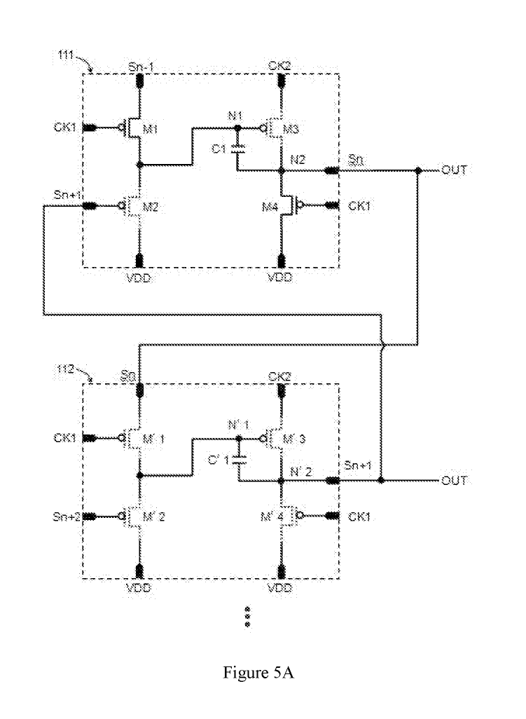

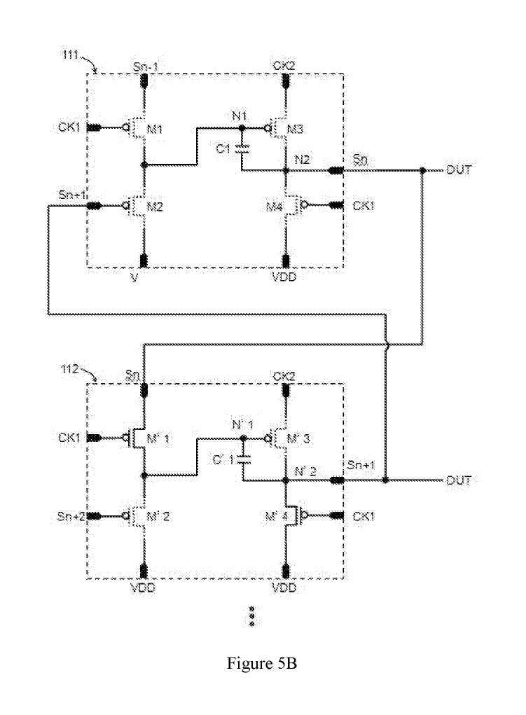

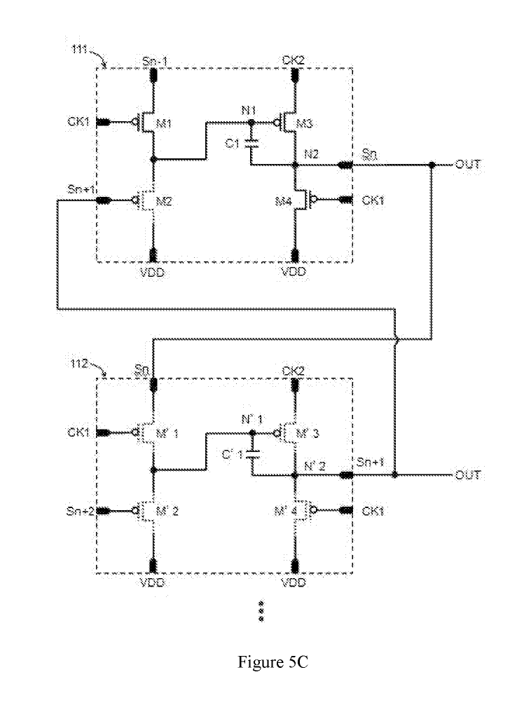

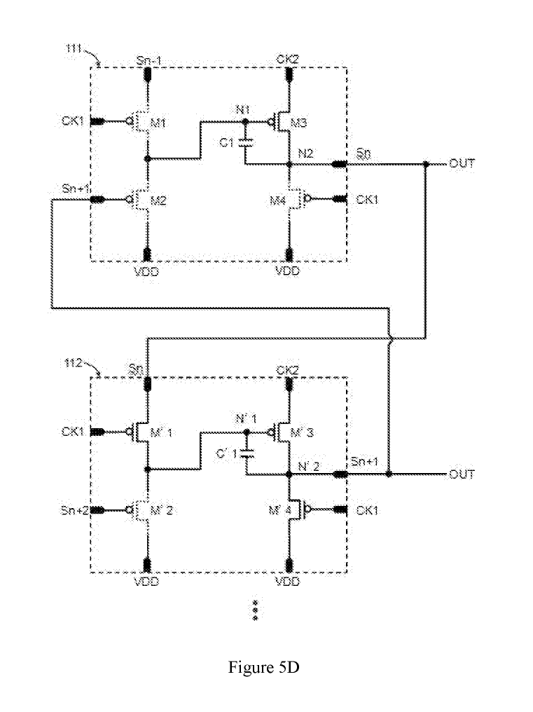

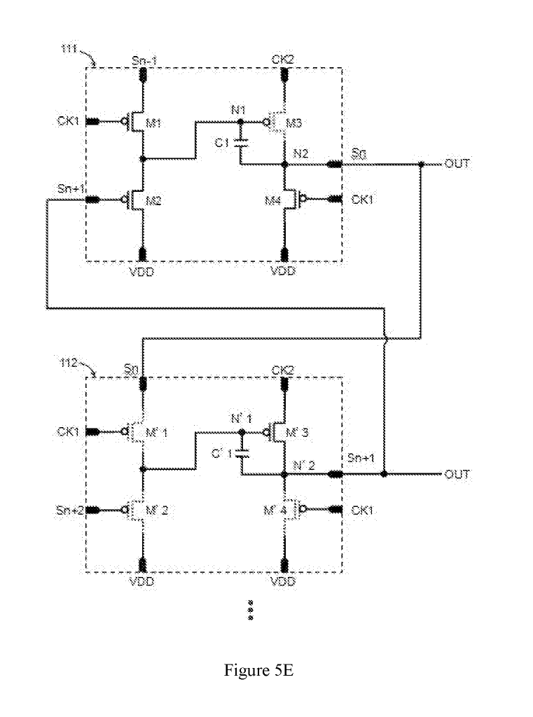

FIGS. 5A-5E respectively shows the working mechanism of the drive module corresponding to the time period T1˜T5.

In FIG. 5A, the switch response action of each transistor of the current-stage driver module 111 and the adjacent previous-stage driver module 112 is in accordance with the first unit period T1 in FIG. 4. Now set the output signals S₁, . . . S_{N-1}, S_{N}, S_{N+1} . . . of each of multistage drive module in the first unit period T1 to the state that at the initialized high level. For the current-stage drive module 111, the gate of the first transistor M1 and the gate of the fourth transistor M4 are at a low potential of the first clock signal CLK and limited at a low logic level, the first transistor M1 and the fourth transistor M4 are switched on. The gate of the second transistor M2 is switched off since it is connected to the second common node N′2 of the next-stage drive module 112 and is switched off due to the high level of the output signal S_{N+1} of the driver module 112, the gate of the third transistor M3 is connected to an input signal IN (that is the output signal S_{N-1} of the previous-stage drive module of the drive module 111) of the first end of the switched-on first transistor M1, and the high level of potential of the output signal S_{N-1} switches off the third transistor M3, meanwhile, the high potential level of the output signal S_{N-1} of the adjacent previous-stage drive module of the drive module 111 is stored at the first common node N1 by bootstrap capacitor C1. So that the output signal S_{N} of the current-stage drive module 111 is the high level reference voltage VDD input in the second end of the switched-on fourth transistor M4, the bootstrap capacitor C1 holds action by the voltage and the bootstrapping also pushes up the voltage level at the first common node N1 due to the high level of the output signal S_{N}.

In FIG. 5A, for the next-stage drive module 112, the gate of the first transistor M′1 and the gate of fourth transistor M′4 are at high potential of the second clock signal CLKB and limited in the high logic level, which makes the first transistor M′1 and the fourth transistor M′4 being switch off. The second transistor M′2 is switched off due to the high level of the output signal SN+2 of the next-stage drive module relative to the drive module 112, and the third transistor M′3 is switched off due to the high level reserved at the first common node N′1 by the action of the previous frame, at this time, the output signal S_{N+1} of drive module 112 is about as close to the initialized high level such as the reference voltage VDD.

FIG. 5B is a response of each transistor caused by the second unit period T2 in FIG. 4, and the second unit period T2 immediately follows the first unit period T1, the output signals S₁, . . . S_{N-1}, S_{N}, S_{N+1} . . . respectively of each of the multistage drive modules are still at the initialized high level. For the current-stage drive module 111, the gate of the first transistor M1 and the gate of the fourth transistor M4 are at high potential of the first clock signal CLK at this time and limited at high logic level, and the first transistor M1 and fourth transistor M4 are switched off. The second transistor M2 is switched off because the output signal SN+1 of the next-stage drive module 112 is high level, and now the first common node N1 turns into floating state, and the third transistor M3 is switched off because the gate potential is equal to the high level stored at the first common node N1 by bootstrap capacitor C1, so the output signal S_{N} of the drive module 111 at this time still remains at a high level of the second common node N2 such as the reference voltage VDD.

In FIG. 5B, for the next-stage drive module 112, the grid control terminal of the first transistor M′1 and the grid control terminal of the fourth transistor M′4 are at a low potential of the second clock signal CLKB at this time and limited at a low logic level, which leads to the first transistor M′1 and the fourth transistor M′4 being switched on. However the second transistor M′2 is switched off since the output signal S_{N+2} of the next-stage drive module relative to the current-stage drive module 112 is a high level, and the gate of the third transistor M3 is connected to an input signal IN (that is the output signal S_{N} of the drive module 111) of the first end of the switched-on first transistor M1, and the high level of potential of the output signal S_{N} switches off the third transistor M3. At the same time, the high potential level of the output signal S_{N} of the selected current-stage drive module 111 is stored at the first common node N1 by bootstrap capacitor C1 of the next-stage drive module 112, so the output signal S_{N+1} of the drive module 112 is about equal to the high level reference voltage VDD input in the second end of the switched-on fourth transistor M′4.

FIG. 5C is a response of each transistor caused by the third unit period T3 in FIG. 4, and the third unit period T3 immediately follows the second unit period T2, note that the output signal S_{N-1} of the previous-stage drive module relative to the current-stage drive module 111 is reversed to a low level at this time, but the output signals S_{N} and S_{N+1} of the drive modules 111 and 112 are still at initialized high level. For the current-stage drive module 111, the gate of the first transistor M1 and the gate of the fourth transistor M4 are at low potential of the first clock signal CLK at this time and limited at low logic level, and the first transistor M1 and fourth transistor M4 are switched on, the second transistor M2 is switched off because the output signal S_{N+1} of the next-stage drive module 112 is high level. The gate of the third transistor M3 is connected to an input signal IN (i.e., the output signal S_{N-1} of the previous-stage drive module relative to the drive module 111) of the first end of the switched-on first transistor M1, and the low level of potential of the output signal S_{N-1} switches on the third transistor M3, at the same time, the low potential level of the output signal S_{N-1} of the adjacent previous-stage drive module relative to the drive module 111 is stored at the first common node N1 by bootstrap capacitor C1. At this stage, since the third transistor M3 is switched on, the output signal S_{N} of the current-stage drive module 111 may be connected to the high potential second clock signal CLKB input in the first end of the third transistor M3, moreover, the fourth transistor M4 is also switched on to ensure the stability of the high level of the output signal S_{N} of the current-stage drive module 111 and maintain the reference voltage VDD level input in the second end of the switched-on fourth transistor M4.

In FIG. 5C, for the next-stage drive module 112, the gate of the first transistor M′1 and the gate of the fourth transistor M′4 are at a high potential of the second clock signal CLKB and limited at a high logic level, which leads to the first transistor M′1 and the fourth transistor M′4 being switched off. The second transistor M′2 is switched off since the output signal S_{N+2} of the next-stage drive module relative to the current-stage drive module 112 is a high level, now the first common node N′1 turns into floating state, and the high potential level of the output signal S_{N} in FIG. 5B is stored at the first common node Ni by bootstrap capacitor C1 in the next-stage drive module 112, and the third transistor M3 is switched off because of the high potential stored at the common node N1 by bootstrap capacitor C1, at this stage, the output signal S_{N+1} of the drive module 112 remains at the level of reference voltage VDD of the second common node N′2.

FIG. 5D is a response of each transistor caused by the forth unit period T4 in FIG. 4, and the fourth unit period T4 closely follows the third unit period T3. Note that during the predetermined cycle period mentioned above, the output signal S_{N-1} of the previous-stage drive module of the current-stage drive module 111 is reversed to a low level during the third unit period T3, but the output signal S_{N-1} has a high logic level state before the third unit period T3 and back to high logic level state after the third unit period T3. The output signal S_{N+1} of the drive module 112 and the output signal S_{N+2} of the next-stage drive module relative to the drive module 112 are still at high level during the fourth unit period T4, and the output signal S_{N-1} is also at high level. For the current-stage drive module 111, the gates of the first transistor M1 and the gate of the fourth transistor M4 are at high potential of the first clock signal CLK at this time and limited at high logic level, so the first transistor M1 and fourth transistor M4 are switched off, and the second transistor M2 is switched off because the output signal S_{N+1} of the next-stage drive module 112 is high level. In addition, the level stored at the first common node N1 in FIG. 5C is low level, so the third transistor M3 in FIG. 5D is switched on because its gate potential approximately equals to the low potential stored at the floating first common node N1 by bootstrap capacitor C1. AT this stage, the output signal S_{N} of the selected current-stage drive module 111 is connected to the first end of the switched-on third transistor M3, and the second clock signal CLKB input in the first end of the third transistor M3 is at low level, such as the reference voltage VEE, so the input of the output signal S_{N} is low level. Then during the fourth unit period T4, it realizes the shifting of the low logic level provided to a signal S_{N-1} of the drive module 111 in the third unit period T3 to the output signal S_{N} of the drive module 111 during the fourth unit period T4.

In FIG. 5D, for the next-stage drive module 112, the gate of the first transistor M′1 and the gate of the fourth transistor M′4 are at a low potential of the second clock signal CLKB at this time and limited at a low logic level, which leads to the first transistor M′1 and the fourth transistor M′4 being switched on. The second transistor M′2 is switched off since the output signal S_{N+2} of the next-stage drive module relative to the current-stage drive module 112 is a high level; the gate of the third transistor M3 is connected to the output signal S_{N} of the drive module 111 input in the first end of the switched-on first transistor M1, and the output signal S_{N} is now at low level so that to switch on the third transistor M3, at the same time, the low potential level of the output signal S_{N} of the selected current-stage drive module 111 is stored at the first common node N′1 by bootstrap capacitor C1 of the drive module 112. Since the third transistor M′3 is switched on, the output signal S_{N+1} of the drive module 112 may be connected to the high potential first clock signal CLK input in the first end of the third transistor M′3, in addition the output signal S_{N+1} of the drive module 112 is connected to the voltage reference VDD input in the second end of the switched-on fourth transistor M′4, which further ensures that the output signal S_{N+1} is at high potential level of the reference voltage VDD.

FIG. 5E is a response of each transistor caused by the fifth unit period T5 in FIG. 4, and the fifth unit period T5 closely follows the fourth unit period T4, note that the output signal S_{N-1} of the previous-stage drive module relative to the current-stage drive module 111 is high level at this stage. For the drive module 111 of this level, the gate of the first transistor M1 and the gate of the fourth transistor M4 are at low potential of the first clock signal CLK at this time and limited at low logic level, so the first transistor M1 and fourth transistor M4 are switched on, the low level at the first common node N1 stored by the bootstrap capacitor C1 turns into a high level because of the high level output signal S_{N-1} input in the first end of the switched-on first transistor Ml, so that the third transistor M3 is switched off, the output signal S_{N} of the current-stage drive module 111 maintains at the voltage reference VDD input in the second end of the switched-on fourth transistor M4.

In FIG. 5E, for the next-stage drive module 112, the gate of the first transistor M′l and the gate of the fourth transistor M′4 are at a high potential of the second clock signal CLKB and limited at a high logic level, which leads to the first transistor M′1 and the fourth transistor M′4 being switched off. The second transistor M′2 is switched off since the output signal S_{N+2} of the next-stage drive module relative to the current-stage drive module 112 is a high level, and the third transistor M′3 is switched on because its gate potential is equal to the low potential stored at the first common node N′1 by bootstrap capacitor C1 in FIG. 5D, at this stage, the output signal S_{N+1} of the drive module 112 is connected to the first clock signal CLK input in the first end of the switched-on third transistor M′3, and the first clock signal CLK is at low level, such as the reference voltage VEE, so the low logic level of the output signal S_{N} of the drive module 111 during the fourth unit period T4 shifts to the output signal S_{N+1} of the drive module 112 during the fifth unit period T5. At this time, since the low level output signal S_{N+1} of the drive module 112 is also supplied to the gate of the second transistor M2 of the drive module 111, so the second transistor M2 of the drive module 111 is switched on, thereby further causes that one end of bootstrap capacitor C1 of the drive module 111 connected to the first common node N1 is coupled to the second end of the second transistor M2 through the switched-on second transistor M2, the above has mentioned that the second end of the second transistor M2 is input high level reference voltage VDD, so the first common node N1 is limited at a high level state, which ensures that the third transistor M3 is switched-off.

Referring again to FIG. 4, during a unit period of time followed after the fifth unit period of time T5, the first clock signal CLK is inverted to a high level and the second clock signal CLKB is inverted to a low level, that is to say during other times after performing the sequential control program T1˜T5 within the whole predetermined period, the first clock signal CLK and the second clock signal CLKB repeat the actions of the unit period T2, T1, but the output signal S_{N} of the current-stage drive module 111 always maintains at high level VDD. Equivalently, for any two adjacent drive modules N−1, N, the output signal S_{N-1} of the previous-stage drive module N−1 has a high logic level state before a predetermined unit period of time T3, but shifts to low logic level state during the predetermined unit period of time T3 and returns to high logic level state after the predetermined unit period of time T3, while the output signal S_{N} of the adjacent next-stage drive module N has a high logic level state before the unit period of time T4 next to the predetermined unit period of time T3, but shifts to low logic level state during the next unit period of time T4 and returns to high logic level state after the next unit period of time T4. Such rule applies to the adjacent two drive modules, because in essence, realizing the shift is one of the objectives of the drive modules in multi-stages of the invention. Ultimately, we will find that, the collection of the output signals S₁, . . . S_{N-1}, S_{N}, S_{N+1} . . . respectively of the drive modules in multi-stages constitutes a series of non-overlapping temporal pulse signals, for example any one of the output signals, such as output signal SN−1, has low level state during the predetermined unit period of time T3, and the adjacent output signal S_{N} has low level state during the next unit period of time T4, but the output signals S_{N-1}, S_{N} will not be overlapping to synchronously enter low level state during any same unit period of time. The series of non-overlapping temporal pulse signals [S₁, . . . S_{N-1}, S_{N}, S_{N+1} . . . ] generated by the drive circuit GOA is typically used as row strobe control signal of the pixel circuit array, for example provides gate control signal for AMOLED pixel circuit.

In some alternative embodiments, the drive module 101 is a first row drive module of a column, that is the drive module 101 has not adjacent previous-stage drive module, so an input signal (e.g., the output signal S_{N-1} need to be provided) coupled to the input signal IN terminal of the drive module 101 cannot be captured from the previous-stage drive module, however we can use a frame open signal STP-1 as the output signal S_{N-1} to provide to the drive module 101, namely use the frame open signal STP-1 (the output signal S_{N-1}) transmitted by other drive elements to trigger the starting of the first drive module 101 in FIG. 4, and to generate the gradual shift effect of the output signal S_{N-1} during the subsequent each unit period of time.

While the present disclosure has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A shift register, comprising drive modules in multi-stages, wherein:
output signals of a current-stage driver module act as reset signals of a previous-stage driver module and act as input signals of a next-stage driver module;
each of the drive modules has a first clock control terminal and a second clock control terminal; in two adjacent drive modules of the drive modules, the first clock control terminal of the previous-stage driver module is driven by a first clock signal, and the second clock control terminal of the previous-stage driver module is driven by a second clock signal inverted with the first clock signal; the first clock control terminal of the next-stage driver module is driven by the second clock signal, and the second clock control terminal of the next-stage driver module is driven by the first clock signal.

2. The shift register according to claim 1, wherein each of the drive modules includes a first node, a second node, a first transistor, a second transistor, a third transistor and a fourth transistor, and each of the transistors has a first end, a second end and a control terminal;
wherein, the second end of the first transistor and the first end of the second transistor are connected to the control terminal of the third transistor through the first node, the second end of the third transistor and the first end of the fourth transistor are connected to the second node, and a bootstrap capacitor is disposed to be connected between the second node and the first node, so as to generate the output signals of each of the drive modules at the second node.

3. The shift register according to claim 2, wherein the control terminals of the first transistor and of the fourth transistor are connected to the first clock control terminal of each of the drive modules, the first end of the third transistor connects to the second clock control terminal of each of the drive modules.

4. The shift register according to claim 2, wherein the first end of the first transistor of the current-stage drive module is configured to receive the input signals and connected to an output signal end of the previous-stage drive module, and the control terminal of the second transistor of the current-stage drive module is configured to receive the reset signals and connected to the output signal ends of the next-stage drive module.

5. The shift register according to claim 2, wherein the second ends of the second transistor and of the fourth transistor are connected to a reference voltage source, so as to receive a high-level reference voltage.

6. The shift register according to claim 1, wherein the drive modules in multi-stages are arranged in a row; the first clock control terminals of the drive modules in odd-numbered rows are driven by the first clock signal, and the second clock control terminals of the drive modules in odd-numbered rows are driven by the second clock signal; the first clock control terminals of the drive modules in even-numbered rows are driven by the second clock signal, and the second clock control terminals of the drive modules in even-numbered rows are driven by the first clock signal.

7. A drive circuit, comprising a first node, a second node, a first transistor, a second transistor, a third transistor and a fourth transistor, and each of the transistors has a first end, a second end, and a control terminal;
wherein, the second end of the first transistor and the first end of the second transistor are connected to the control terminal of the third transistor through the first node; the second end of the third transistor and the first end of the fourth transistor are connected to the second node, and a bootstrap capacitor is disposed to be connected between the second node and the first node, so as to generate the output signal of the drive module at the second node.

8. The drive circuit according to claim 7, further comprising:
a first clock control terminal, connecting the control terminal of the first transistor and the control terminal of the fourth transistor;
a second clock control terminal, connecting the first end of the third transistor;
wherein, the first end of the first transistor is configured to receive an input signal, and the control terminal of the second transistor is configured to receive a reset signal.

9. The drive circuit according to claim 7, wherein the second end of the second transistor and that of the fourth transistor are connected to a reference voltage source, so as to receive a high-level reference voltage.

10. The drive circuit according to claim 7, wherein the first transistor, the second transistor, the third transistor and the fourth transistor are all PMOS transistors.
